(19) United States
(12) Patent Application Publication
(10) Pub. No.: US 2015/0279716 A1
(43) Pub. Date: Oct. 1, 2015

(54) APPARATUS AND METHOD FOR DETACHING CHIP

(71) Applicant: PROTEC CO., LTD., Incheon (KR)

(72) Inventor: YOUN SUNG KO, CHUNGCHEONGNAM-DO (KR)

(21) Appl. No.: 14/670,415

(22) Filed: Mar. 27, 2015

(30) Foreign Application Priority Data
Apr. 1, 2014 (KR) 10-2014-0038657

(51) Int. Cl. H01L 21/683

(52) U.S. Cl. CPC H01L 21/6836

(57) ABSTRACT

Provided are an apparatus and method for detaching a chip, in which a semiconductor chip attached to a tape is detached so as to supply and mount the semiconductor chip on a package or a circuit board. Accordingly, a semiconductor chip may be effectively detached from a tape while minimizing an impact transferred to the semiconductor chip.

### RELATED APPLICATION

This application claims the benefit of Korean Patent Application No. 10-2014-0038657, filed on Apr. 1, 2014, in the Korean Intellectual Property Office, the disclosure of which is incorporated herein in its entirety by reference.

### BACKGROUND

1. Field

One or more exemplary embodiments relate to an apparatus and method for detaching a chip, and more particularly, to an apparatus and method for detaching a semiconductor chip attached to a tape so as to supply and mount the semiconductor chip on a package or a circuit board.

2. Description of the Related Art

A semiconductor chip formed on a wafer is attached to a thin adhesive tape and is transferred to a next process.

FIG. 1 illustrates an example of semiconductor chips C attached to a tape T to be supplied. A wafer on which multiple semiconductor chips are formed is attached to a thin tape and is sawn into individual semiconductor chips. After the sawing, when the tape T is uniformly pulled by applying a tensile force to the tape T, the plurality of semiconductor chips C are attached to the tape T at predetermined distances as illustrated in FIG. 1.

As illustrated in FIG. 1, the multiple semiconductor chips C attached to the tape T are sequentially detached from the tape T one by one and attached to a circuit board. Recently, such semiconductor chips C having a very thin thickness are being manufactured. If a semiconductor chips C is thin, the semiconductor chip C may be easily damaged when detaching the same from the tape T. In particular, if an area of a semiconductor C is relatively large compared to a thickness thereof, the semiconductor chip C may be easily damaged due to an adhesive force between the tape T and the semiconductor chip C when detaching the semiconductor chip C from the tape T. According to the related art, the tape T is fixed and is pushed up from a lower portion thereof by using a pin to thereby detach a boundary of the semiconductor chip C from the tape T. Then the semiconductor chip C whose boundary is detached from the tape T is lifted using a pick-up head and attached to a circuit board. When pushing up the tape T by using a pin as described above, the semiconductor chip C is damaged due to an impact of the pin against the semiconductor chip C. Also, if an area of the semiconductor chip C is relatively large compared to a thickness thereof as described above, even if the tape T is pushed up by using a pin, the tape T may be elastically deformed or torn, but the semiconductor chip C may not be detached from the tape T.

### SUMMARY

One or more exemplary embodiments include an apparatus and method for detaching a chip, in which a semiconductor chip may be effectively detached from a tape while minimizing an impact applied to the semiconductor chip.

Additional aspects will be set forth in part in the description which follows and, in part, will be apparent from the description, or may be learned by practice of the presented embodiments.

According to one or more exemplary embodiments, a chip detaching apparatus for detaching a semiconductor chip adhered to a thin tape, includes: an eject hood comprising a support body supporting a bottom surface of the tape along an outer circumference of the semiconductor chip that is to be detached from the semiconductor chip, an adsorption hole formed in a top surface of the support body so as to adsorb a portion of the bottom surface of the tape contacting the support body, and a push hole formed to vertically pass through a center portion of the top surface of the support body; a lifting member comprising a lifting body that is vertically liftably installed by being inserted into the push hole of the eject hood so as to upwardly push, through the push hole, the tape adsorbed by a vacuum transferred through the adsorption hole of the eject hood, and a membrane hole formed to vertically pass through a center portion of a top surface of the lifting body; an elastic membrane that is installed in the membrane hole of the lifting member, wherein the elastic membrane is elastically deformed to an upwardly convex form by a pressure transmitted through the membrane hole of the lifting member so as to push up the tape together with the semiconductor chip; and a pick-up head disposed above the eject hood and adsorbing and lifting the semiconductor chip that is to be pushed up by the membrane to thereby detach the semiconductor chip.

According to one or more exemplary embodiments, a chip detaching method for detaching a semiconductor chip adhered to a thin tape, includes: (a) adsorbing a portion of a bottom surface of the tape, which is disposed on an eject hood, through a plurality of adsorption holes formed in a top surface of the eject hood, the portion of the bottom surface of the tape being along an outer circumference of the semiconductor chip which is to be detached from the tape; (b) lifting a lifting member inserted into a push hole formed in a center portion of the eject hood to push up a portion of the tape contacting the lifting member; (c) applying a pressure to an elastic membrane installed in a membrane hole formed in a center portion of the lifting member to elastically deform the membrane to an upwardly convex form so as to detach a portion of the tape around the semiconductor chip from the semiconductor chip; (d) adsorbing a top surface of the semiconductor chip by descending a pick-up head disposed above the eject hood; and (e) detaching the semiconductor chip from the tape by lifting the pick-up head which has adsorbed the semiconductor chip in (d).

### BRIEF DESCRIPTION OF THE DRAWINGS

These and/or other aspects will become apparent and more readily appreciated from the following description of the embodiments, taken in conjunction with the accompanying drawings in which:

FIG. 1 is a plan view illustrating a semiconductor chip adhered to a tape;

FIG. 2 is a plan view illustrating a chip detaching apparatus according to an exemplary embodiment of the present disclosure, in which a tape to which a semiconductor chip is adhered is placed; and

FIGS. 3 through 7 are cross-sectional views of a method of detaching a semiconductor chip by using the chip detaching apparatus illustrated in FIG. 2, cut along a line II-II of FIG. 2.

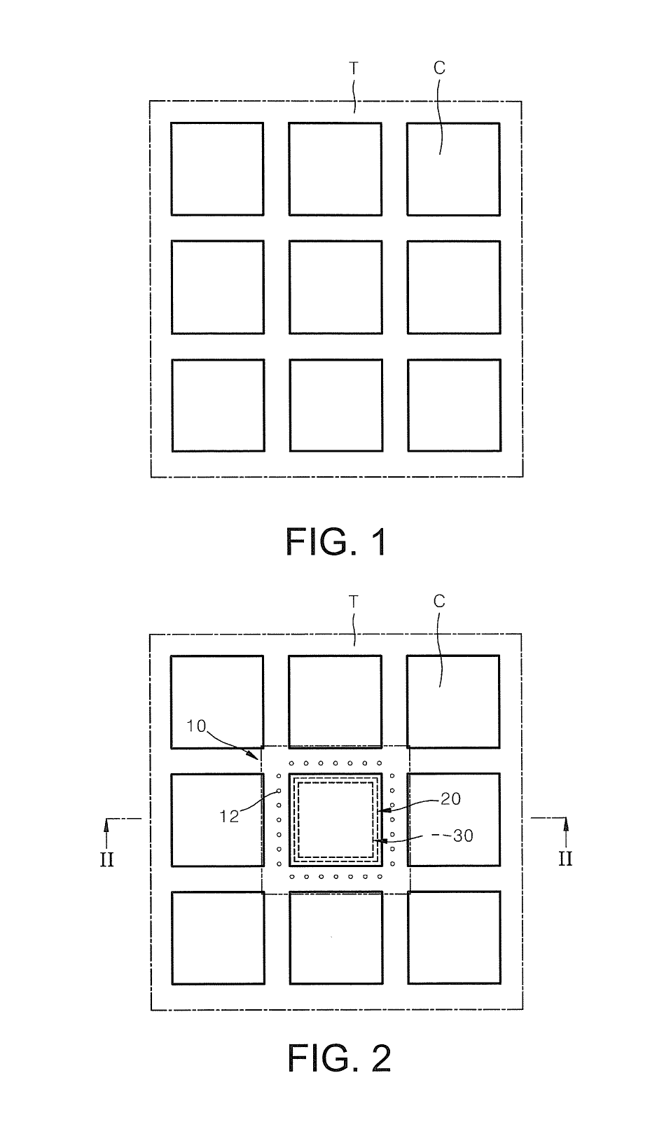

### DETAILED DESCRIPTION

The inventive concept will now be described more fully with reference to the accompanying drawings, in which exemplary embodiments of the inventive concept are shown.

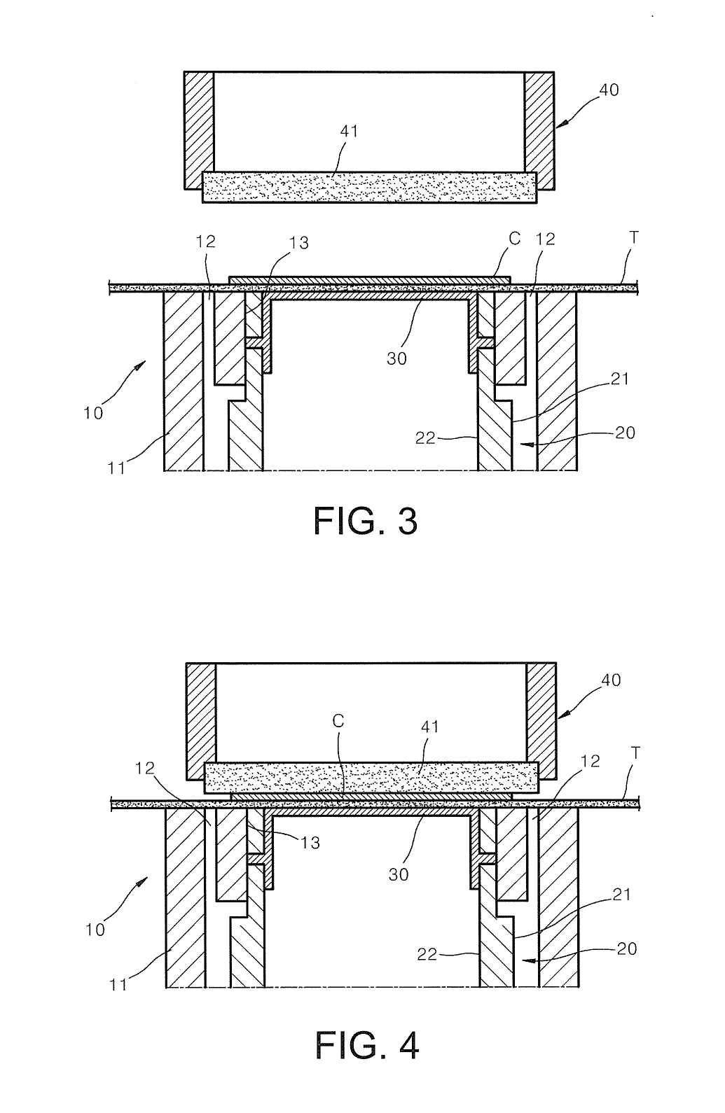

FIG. 2 is a plan view illustrating a chip detaching apparatus according to an exemplary embodiment of the present disclosure, in which a tape T to which a semiconductor chip C is adhered is placed. FIG. 3 is a cross-sectional view of the chip detaching apparatus illustrated in FIG. 2 cut along a line II-II.

Referring to FIGS. 2 through 7, the chip detaching apparatus according to the present exemplary embodiment includes an eject hood 10, a lifting member 20, a membrane 30, and a pick-up head 40.

The eject hood 10 includes a supporting body 11, an adsorption hole 12, and a push hole 13. The supporting body 11 has a shape similar to a quadrangular pipe extending vertically. A top surface of the supporting body 11 has a quadrangular outer circumference. The outer circumference of the top surface of the supporting body 11 is formed to be greater than an outer circumference of the semiconductor chip C that is to be detached from the tape T. A plurality of adsorption holes 12 are formed on the top surface of the supporting body 11. The eject hood 10 generates a vacuum through the adsorption holes 12 so as to adsorb a portion of a bottom surface of the tape T contacting the adsorption holes 12. Referring to FIG. 2, the adsorption holes 12 are arranged along an outer circumference of the semiconductor chip C. The adsorption holes 12 may preferably be arranged between semiconductor chips C adhered to the tape T to adsorb the tape T. The push hole 13 that vertically passes through the supporting body 11 is formed in a center portion of the top surface of the supporting body 11. Accordingly, the adsorption holes 12 are arranged along an outer circumference of the push hole 13. A size of the push hole 13 may preferably be a little smaller than a size of the semiconductor chip C.

The lifting member 20 includes a lifting body 21 and a membrane hole 22. An upper portion of the lifting body 21 is liftably inserted into the push hole 13 of the eject hood 10. An outer circumference of a top surface of the lifting body 21 has a quadrangular shape which fits the size of the push hole 13. The outer circumference of the top surface of the lifting body 21 may preferably be smaller than the size of the semiconductor chip C. The membrane hole 22 is formed in a center portion of the top surface of the lifting body 21. The membrane hole 22 is formed to vertically pass through the center portion of the top surface of the lifting body 21. The membrane hole 22 has a quadrangular contour.

The membrane 30 is installed by being inserted into the membrane hole 22 of the lifting member 20. The membrane 30 has a shape fitting an inner circumference of the membrane hole 22 so as to cover and close a top surface of the membrane hole 22. The membrane 30 is formed of a thin elastic film that is elastically deformable by an air pressure.

The pick-up head 40 is placed above the eject hood 10. The pick-up head 40 includes an adsorption plate 41 formed of a porous ceramic. The pick-up head 40 is configured to move up and down with the adsorption plate 41. The pick-up head 40 brings the adsorption plate 41 into contact with a top surface of the semiconductor chip C so as to adsorb the semiconductor chip C, and then lifts the semiconductor chip C in the adsorbed state to thereby detach the semiconductor chip C from the tape T.

Hereinafter, a method of detaching the semiconductor chip C by using the chip detaching apparatus having the above-described structure will be described.

First, as illustrated in FIGS. 2 and 3, from among semiconductor chips C that are adhered to the tape T, one semiconductor chip C that is to be detached is placed on a top surface of the eject hood 10 and the lifting member 20. Then, a vacuum is transferred to the tape T through the adsorption holes 12 of the eject hood 10 to adsorb a bottom surface of the tape T to the top surface of the eject hood 10 (step (a)).

Next, as illustrated in FIG. 4, the pick-up head 40 placed above the eject hood 10 is descended so that the pick-up head 40 contacts the top surface of the semiconductor chip C to adsorb the semiconductor chip C (step (d)). As described above, a vacuum is transferred to the semiconductor chip C through the adsorption plate 41 of the pick-up head 40 to thereby adsorb the top surface of the semiconductor chip C.

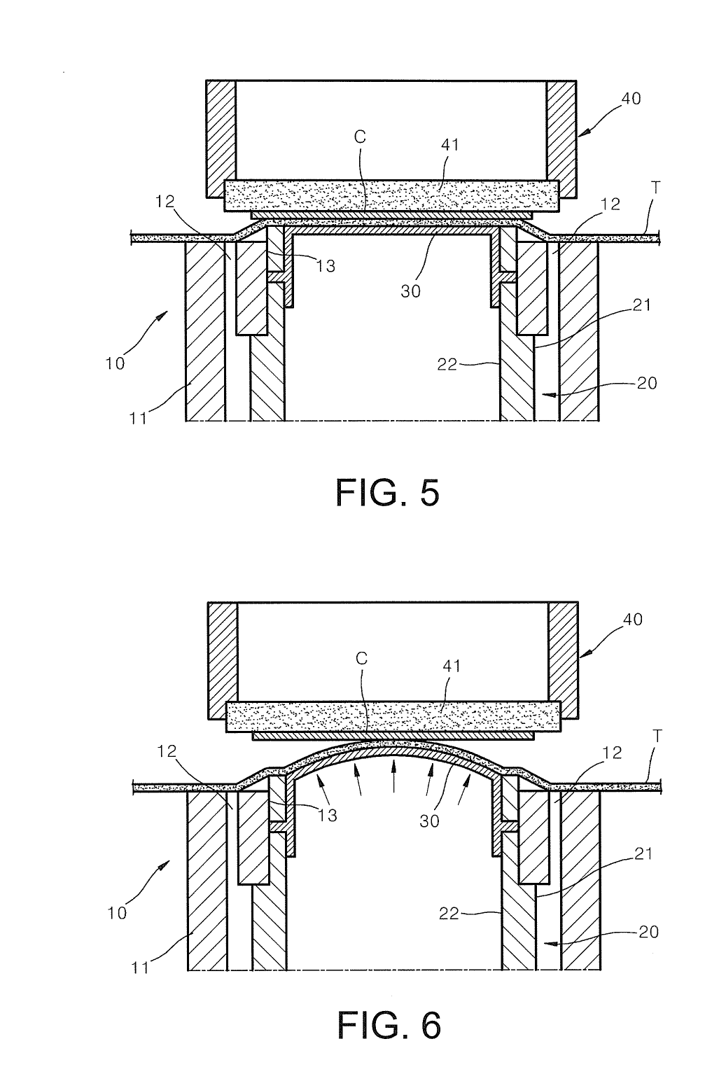

Next, as illustrated in FIG. 5, the lifting member 20 is lifted so that a boundary portion of the semiconductor chip C is detached from the tape T (step (b)). When an outer circumference of the top surface of the lifting member 20 is smaller than an outer circumference of the semiconductor chip C as described above, detaching of the tape T starts from the boundary portion of the semiconductor chip C. As the tape T in an outer portion of the semiconductor chip C is fixed via the adsorption holes 12 as described above, when the semiconductor chip C and the tape T under the semiconductor chip C are lifted by the lifting member 20, a portion of the tape T corresponding to an outer circumference of the semiconductor chip C is detached from the semiconductor chip C. Meanwhile, when the semiconductor chip C is lifted by the lifting member 20, the pick-up head 40 is also lifted in synchronization with movement of the lifting member 20 (step (e)). Thus, as the pick-up head 40 is lifted in synchronization with the movement of the lifting member 20, damages to the semiconductor chip C may be prevented.

Next, as illustrated in FIG. 6, by applying a pressure to the membrane 30 from below the membrane 30 so as to elastically deform the membrane 30 to an upwardly convex form and to thereby push the tape T and the semiconductor chip C upwards (step (c)). Also in this case, the pick-up head 40 lifts the semiconductor chip C in synchronization with movement of the membrane 30 (step (e)). During the elastic deformation of the membrane 30 to a convex form, a portion of the bottom surface of the tape T that is not supported by the membrane 30 is gradually detached from a bottom surface of the semiconductor chip C. That is, detaching (separation) of the tape T is conducted from an outer circumference toward a center portion of the semiconductor chip C. As the detaching the semiconductor chip C is conducted while supporting the tape T by a pressure acting upon the membrane 30 as described above, the tape T may be effectively detached from the bottom surface of the semiconductor chip C. Also, as the tape T may be detached from the bottom surface of the semiconductor chip C according to continuous elastic deformation of the membrane 30, a detaching operation may be efficiently performed without causing damages to the semiconductor chip C by an adhesive force of the tape T. The membrane 30 may be elastically deformed by applying an air pressure to the membrane hole 22 as described above. In other cases, the membrane 30 may be elastically deformed by pressurizing a liquid such as oil into the membrane hole 22.

While performing the step of lifting the lifting member 20 (step (b)) and the step of lifting the membrane 30 (step (c)) as described above, the step of lifting the pick-up head 40 (step (e)) is simultaneously continuously performed.

According to circumstances, instead of descending the pick-up head 40 to adsorb the semiconductor chip C after adsorbing the tape T through the adsorption hole 12 as described above, the chip detaching apparatus may be operated such that steps up to the step of lifting the lifting member 20 (step (b)) are performed, and then the pick-up head 40 is descended to adsorb the semiconductor chip C (step (d)).

Also, according to circumstances, the chip detaching apparatus may be operated such that the pick-up head 40 is descended to adsorb the semiconductor chip C (step (d)) after performing the step of lifting the lifting member 20 up (step (b)) and the step of lifting the membrane 30 (step (c)).

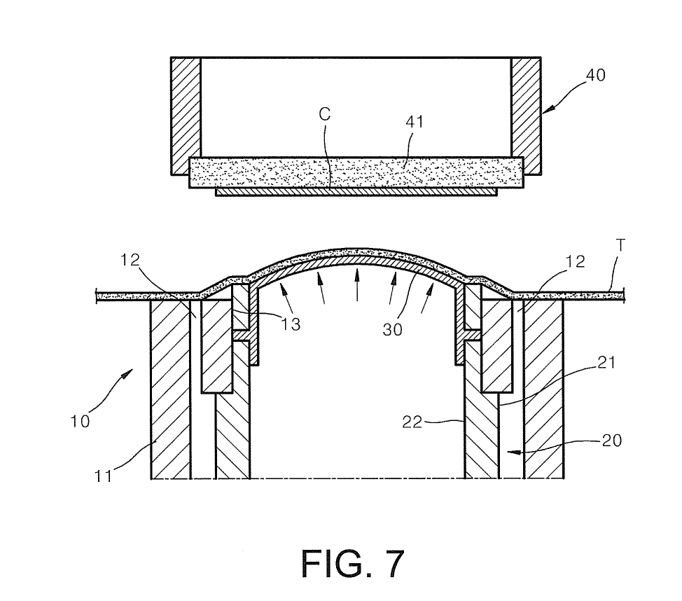

After the semiconductor chip C is detached from the tape T as illustrated in FIG. 7, a pressure in the membrane hole 22 is removed so that the membrane 30 is planar again as is illustrated in FIGS. 3 through 5. According to circumstances, detaching of the semiconductor chip C may be performed such that the pressure in the membrane hole 22 is rapidly reduced after the semiconductor chip C is detached to some extent as illustrated in FIG. 6. When the membrane 30 that is elastically deformed to a convex form instantaneously returns to a planar shape, a portion of the tape T contacting the membrane 30 also instantaneously returns to a planar shape so that the tape T is completely detached from the bottom surface of the semiconductor chip C.

As described above, according to the chip detaching apparatus and the chip detaching method of the one or more of the above exemplary embodiments, a semiconductor chip attached to a tape may be effectively detached while preventing damages to the semiconductor chip.

It should be understood that the exemplary embodiments described therein should be considered in a descriptive sense only and not for purposes of limitation. Descriptions of features or aspects within each embodiment should typically be considered as available for other similar features or aspects in other embodiments.

While one or more exemplary embodiments have been described with reference to the figures, it will be understood by those of ordinary skill in the art that various changes in form and details may be made therein without departing from the spirit and scope of the inventive concept as defined by the following claims.

What is claimed is:

1. A chip detaching apparatus for detaching a semiconductor chip adhered to a thin tape, the chip detaching apparatus comprising:
an eject hood comprising a support body supporting a bottom surface of the tape along an outer circumference of the semiconductor chip that is to be detached from the semiconductor chip, an adsorption hole formed in a top surface of the support body so as to adsorb a portion of the bottom surface of the tape contacting the support body, and a push hole formed to vertically pass through a center portion of the top surface of the support body;
a lifting member comprising a lifting body that is vertically liftably installed by being inserted into the push hole of the eject hood so as to upwardly push, through the push hole, the tape adsorbed by a vacuum transferred through the adsorption hole of the eject hood, and a membrane hole formed to vertically pass through a center portion of a top surface of the lifting body;
an elastic membrane that is installed in the membrane hole of the lifting member, wherein the elastic membrane is elastically deformed to an upwardly convex form by a pressure transmitted through the membrane hole of the lifting member so as to push up the tape together with the semiconductor chip; and
a pick-up head disposed above the eject hood and adsorbing and lifting the semiconductor chip that is to be pushed up by the membrane to thereby detach the semiconductor chip.

2. The chip detaching apparatus of claim 1, wherein a plurality of adsorption holes are formed in the eject hood and arranged along an outer circumference of the push hole.

3. The chip detaching apparatus of claim 2, wherein an outer circumference of the lifting member is smaller than an outer circumference of the semiconductor chip.

4. The chip detaching apparatus of claim 3, wherein the tape is adsorbed through the plurality of adsorption holes of the eject hood along the outer circumference of the semiconductor chip.

5. The chip detaching apparatus of claim 1, wherein after the eject hood adsorbs the tape, and the pick-up head adsorbs the semiconductor chip, the lifting member is lifted so as to lift the tape and the semiconductor chip disposed above the lifting member.

6. The chip detaching apparatus of claim 5, wherein after the tape and the semiconductor chip are lifted by the lifting member, a pressure in the membrane hole is increased to elastically deform the membrane so that the tape and the semiconductor chip are pushed up by the membrane.

7. The chip detaching apparatus of claim 5, wherein when the semiconductor chip is pushed up by the lifting member and the membrane, the pick-up head lifts the semiconductor chip, which is adsorbed on the pick-up head, to thereby detach the semiconductor chip from the tape.

8. A chip detaching method for detaching a semiconductor chip adhered to a thin tape, the chip detaching method comprising:
(a) adsorbing a portion of a bottom surface of the tape, which is disposed on an eject hood, through a plurality of adsorption holes formed in a top surface of the eject hood, the portion of the bottom surface of the tape being along an outer circumference of the semiconductor chip which is to be detached from the tape;
(b) lifting a lifting member inserted into a push hole formed in a center portion of the eject hood to push up a portion of the tape contacting the lifting member;
(c) applying a pressure to an elastic membrane installed in a membrane hole formed in a center portion of the lifting member to elastically deform the membrane to an upwardly convex form so as to detach a portion of the tape around the semiconductor chip from the semiconductor chip;
(d) adsorbing a top surface of the semiconductor chip by descending a pick-up head disposed above the eject hood; and
(e) detaching the semiconductor chip from the tape by lifting the pick-up head which has adsorbed the semiconductor chip in (d).

9. The chip detaching method of claim 8, wherein (d) is performed after performing (a), and
while performing (b) and (c), in (e), the semiconductor chip is lifted using the pick-up head in synchronization with operations of the eject hood and the membrane.

10. The chip detaching method of claim 8, wherein (d) is performed after performing (a) and (b), and
while performing (c), in (e), the semiconductor chip is lifted using the pick-up head in synchronization with an operation of the membrane.

11. The chip detaching method of claim 8, wherein (d) and (e) are performed after performing (a), (b), and (c).

12. The chip detaching method of claims 8, wherein in (b), the semiconductor chip is pushed up by using the lifting member, an outer circumference of which is smaller than an outer circumference of the semiconductor chip.
